(19) United States
(12) Patent Application Publication
(10) Pub. No.: US 2006/0284173 A1
(43) Pub. Date: Dec. 21, 2006

(54) Method to test shallow trench isolation fill capability

(75) Inventors: Manuel A. Quevedo-Lopez, Plano, TX (US); Yung-Shan Chang, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/155,149

(22) Filed: Jun. 17, 2005

(51) Int. Cl. H01L 23/58; H01L 29/10

(52) U.S. Cl. 257/48

(57) ABSTRACT

A shallow trench isolation (STI) test pattern comprising a plurality of test structures. Each of the test structures comprise at least two lines comprising a predefined line length, line width, and gap between the lines. At least one of the line length, line width and gap are different between each of the plurality of the test structures.

### TECHNICAL FIELD OF THE INVENTION

The present invention relates generally to microelectronic devices, and more particularly, to methods and structures for testing the formation shallow trench isolation (STI) structures used to separate active areas.

### BACKGROUND OF THE INVENTION

In the fabrication of microelectronic devices, isolation structures are formed between active areas in which electrical devices such as transistors, memory cells, or the like are formed. The push for smaller device sizes and increased device densities results in less area that can be dedicated to isolation spaces. Conventional trench isolation techniques must continually adapt to meet the demands of relatively smaller large isolation spaces. For instance as device dimensions scaled below the 0.25 micron technology node, isolation by the local oxidation of silicon (LOCOS) has been largely replaced by shallow trench isolation (STI).

As device dimensions reach the sub-0.100 micron technology node, new problems arise. For instance, it is becoming increasing difficult to ensure the complete filling of STI structures with insulating material. In particular, it is difficult to fill small STI dimensions without voids forming in the trench. The presence of voids causes improper isolation between devices. Improper isolation between microelectronic devices can severely degrade integrated circuit performance. Improper isolation among highly integrated devices causes current leakage, which in turn increases power consumption. Improper isolation also can exacerbate latch-up, which damages the circuit temporarily or permanently. Furthermore, improper isolation can result in noise margin degradation, voltage shift and crosstalk.

Accordingly, what is needed in the art is a method to determine whether or areas selected for STI structures can be filled with insulating materials that are substantially free of voids.

### SUMMARY OF THE INVENTION

To address the above-discussed deficiencies of the prior art, the present invention provides in one embodiment, a shallow trench isolation (STI) test pattern. The test pattern comprises a plurality of test structures. Each of the test structures comprise at least two lines comprising a predefined line length, line width, and gap between the lines. At least one of the line length, line width and gap are different between each of the plurality of the test structures.

Another aspect of the present invention is a method of testing a STI design rule. The method comprises defining the above-described STI test pattern in a substrate. The method also comprises filling the STI test pattern with an insulating material and determining whether voids are present in the insulator-filled STI test pattern. The method further comprises accepting a design rule for a void-free test structure of the insulator-filled STI test pattern.

Still above aspect of the present invention is a method of manufacturing an integrated circuit. The method comprises using the above-described method of testing the design rules for a STI structure. The method further comprises filling the STI test pattern with an insulator, determining whether voids are present in the insulator-filled STI test pattern and accepting a design rule for a void-free test structure of the insulator-filled STI test pattern. The method also comprises forming active areas in a device substrate and forming STI structures in the device substrate to electrically isolate the active areas, wherein the STI structures obey the accepted design rule.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiments as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

For a more complete understanding of the present invention, reference is now made to the following detailed description taken in conjunction with the accompanying FIGUREs. It is emphasized that various features may not be drawn to scale. In fact, the dimensions of various features may be arbitrarily increased or reduced for clarity of discussion. In addition, it is emphasized that some circuit components may not be illustrated for clarity of discussion. Reference is now made to the following descriptions taken in conjunction with the accompanying drawings, in which:

FIG. 1 presents a plan view of an exemplary shallow trench isolation (STI) test pattern;

FIG. 2 illustrates by flow diagram selected steps of an embodiment of a method of testing an STI design rule that follows the principles of the present invention; and

FIGS. 3-9 illustrate plan and cross-sectional views of an exemplary integrated circuit at selected stages of manufacture following the principles of the present invention.

### DETAILED DESCRIPTION

The present invention recognizes the benefit of using a test pattern to evaluate whether or not proposed design rules for an integrated circuit layout will provide void-free STI structures. The STI test pattern is configured to provide information about design parameters that affect the ability of isolation trenches to be filled with insulating material in a void-free manner. The use of such a test pattern provides substantially more information about these STI design parameters in a shorter period and at less expense than current approaches.

Current approaches require the manufacturing the active areas using a proposed integrated circuit design on a substrate, filling the STI structures between the active areas with an insulator, and then analyzing the STI structures in the substrate for the presence of voids. The dimensions of STI structures in the circuit are increased or decreased by adjusting the lithographic exposure settings when patterning the circuit design, thereby globally changing the size of active areas. The active areas and STI structures formed in different substrates and the STI structures are re-analyzed for void formation. The entire process is repeated until a circuit design that is capable of providing void-free STI structures is obtained. In contrast, by providing a plurality of test structures in a single test substrate, the STI test pattern of the present invention can be used to determine design rules for the fabrication of void-free STI structures in a single test on a single substrate.

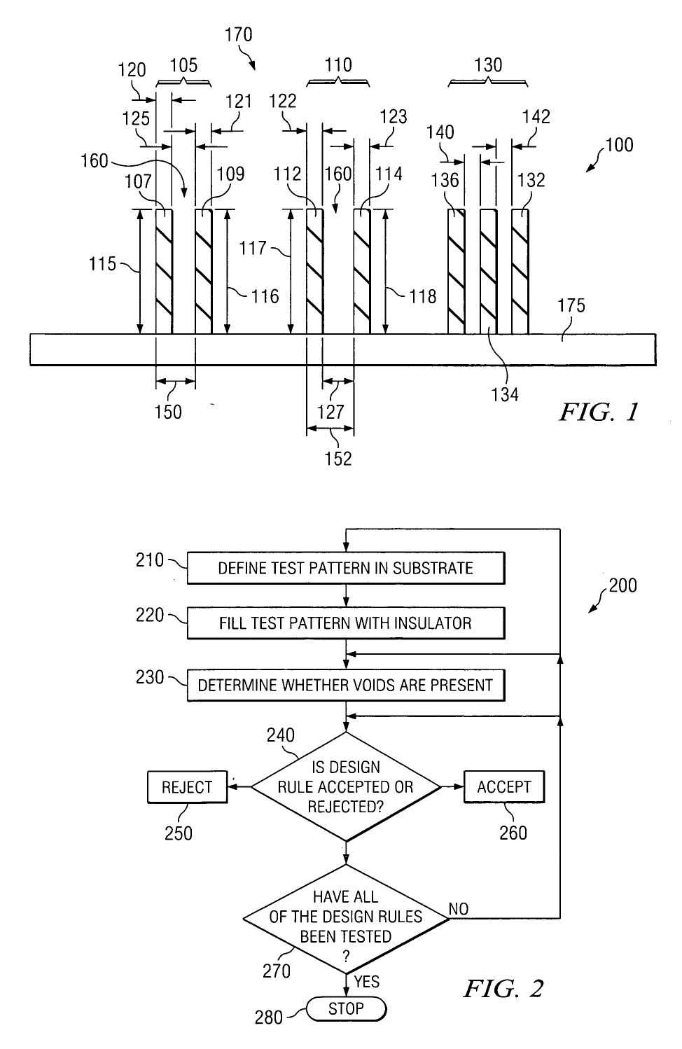

One embodiment of the present invention is a shallow trench isolation (STI) test pattern. The test pattern comprises a plurality of test structures, each of the test structures comprising at least two lines comprising a predefined line length, line width, and gap between the lines. FIG. 1 presents a plan view of an exemplary shallow trench isolation (STI) test pattern 100. The exemplary test pattern 100 comprises a first test structure 105 having two lines 107, 109 and a second test structure 110, having two lines 112, 114. The lines 107, 109, 112, 114 comprise a predefined line length 115, 116, 117, 118, line width 120, 121, 122, 123, and gap 125, 127 between the lines 107, 109, 112, 114.

Some preferred embodiments of the test pattern 100 comprise a third test structure 130 that comprises at least three lines 132, 134, 136. In some cases each of the test structures of the test pattern 100 comprise at least three lines while in other cases only some of the test structures comprise at least three lines. The presence of at least three lines 132, 134, 136 advantageously provides at least at two gaps 140, 145 per test structure 130, thereby providing additional information about this parameter. In some cases it is desirable for the gaps 140, 145 within any one of the test structures 130 to be substantially equal to each other. In other cases, however, it is advantageous for the gaps 140, 145 within the test structure 130 to have different values from each other.

The specific distances of the line length 115, 116, 117, 118, line width 120, 121, 122, 123, and gap 125, 127 will affect the likelihood that a trench defined by these design parameters will include a void when filled with insulating material. For example, when using typical STI filling procedures it is more difficult to fill a narrow trench with no voids between two active areas, as modeled by a small gap between two lines, as compared to a wide trench. Similarly, there is a greater tendency for voids to be formed when filling a trench located between two long or wide active areas, as modeled by a gap between two long lines or between two wide lines, as compared to trench located between two short or two narrow active areas.

At least one of the line length, line width and gap are different between each of the plurality of the test structures. For instance, in some test patterns, the line length and line width between all or a portion of the test structures is held constant while the gap between the lines is varied. For example, for the test pattern 100 illustrated in FIG. 1, the lengths 115, 116 and widths 120, 121 of the lines 107, 109 of the first test structure 105, are substantially equal. That is, the line lengths 115, 116 are substantially the same length as each other and the line widths 120, 121 are substantial the same width as each other. In some embodiments of the test pattern 100, the gap 125 between the lines 107, 109 of the first test structure is adjusted to be different than the gap 127 between the second test structure 110 or any other test structures of the test pattern 100.

Any one, two, or all of the design parameters can be adjusted between test structures. For example, in some cases to facilitated identification and characterization of voids, it is advantageous for just one of the line length 115, 116, 117, 118, line width 120, 121, 122, 123, or gap 125, 127, to be different between adjacent test structures 105, 110. In other cases, however, any two or all three of the line length 115, 116, 117, 118, line width 120, 121, 122, 123, or gap 125, 127 are different between adjacent test structures 105, 110.

In some cases it is desirable to adjust the line length, line width and gap within a predefined range and by uniform increments between test structures, and more preferably between adjacent test structures. The selected range of values of the line length 115, 116, 117, 118, line width 120, 121, 122, 123, and gap 125, 127 and their incremental increase between test structures depend multiple factors, including the type insulator used and the method for filling the trench and the technology node of interest.

Consider as an example a situation where the goal is to evaluate filling a trench with silicon dioxide via chemical vapor deposition (CVD) for the 65 nm technology node. In some preferred embodiments, the line length 115, 116, 117, 118 ranges from about 180 to about 1000 nanometers. In other embodiments the line width 120, 121, 122, 123 ranges from about 90 to about 120 nanometers. In still other embodiments the gap 125, 127 ranges from about 60 to about 90 nanometers. The increment by which these parameters are adjusted between test structures 105, 110 typically ranges from 5 to 30 percent of the full range of the STI design parameter of interest. Of course, one of ordinary skill in the art would understand how to adjust these STI design parameters to other ranges for further testing at this or different technology nodes.

As part of the present invention it was discovered that the pitch between lines is an important design parameter that can be used to test circuit designs for their likelihood of void-formation. The term pitch as used herein refers to the distance of the line width plus the gap. As an example, for the test pattern 100 present in FIG. 1 the line width 115 and the gap 125 to define a pitch 150. Of course the pitch 150, 152 can be varied between the test structures 105, 110 by changing the line width 120, 121, 122, 123, the gap 125, 127 or both between test structures 105, 110.

In some cases, it is desirable to adjust the ratio of the pitch with respective to one or more of line length, line width and gap between test structures. In some instances, the ratio of the pitch 150, 152 to the line length 115, 116, 117, 118 ranges from about 0.1:1 to about 1:1. In other instances, a ratio of the pitch 150 to the line width 120, 121, 122, 123 ranges from about 1.5:1 to about 2:1. In yet other instances, a ratio of the pitch 150, 152 to the gap 125, 127 ranges from about 0.2:1 to about 0.7:1. of course, ratios outside of these ranges are also within the scope of the present invention. Moreover, other ratios of line length, line width and gap, or other parameters, can be used to test STI fill capability according to the principles of the present invention.

In some instances the test pattern 100 is embodied in a reticle 170 that is used to define a pattern in a substrate. In some cases, each one of the test structures 105, 110 correspond to a device under test (DUT) module in the reticle and each one of the lines 107, 109, 112, 114 corresponds to a chromes in the DUT modules. The lines 107, 109, 112, 114, embodied as chromes, can be attached to a cross bar 175 of the reticle 150.

In other instances the test pattern 100 is embodied as a pattern in a substrate. For example the test structures 105, 110 and lines 107, 109, 112, 114 can be configured to define exposure zones over a semiconductor substrate. Portions of the substrate over the exposure zones are etched using conventional lithography procedures to define trenches that are filled with an insulator. The exposure zones, and hence the trenches, correspond to areas 160 between adjacent lines 107, 109, 112, 114 of the test pattern 100. As further discussed below the ensuing structure is inspected for the presence of voids of course, inverse configurations, where the exposure zones and trenches correspond to the lines 107, 109 of the test pattern 100, are also within the scope of the invention.

Another embodiment of the present invention is a method of testing a STI design rule. FIG. 2 illustrates by flow diagram selected steps of an embodiment of a method of testing 200 that follows the principles of the present invention.

The method of testing 200 comprises defining a STI test pattern in a substrate in step 210. In certain preferred embodiments, the defining step 210 comprises using a reticle comprising the STI test pattern to lithographically define exposure zones over a semiconductor substrate. In some preferred embodiments, the defining step 210 also comprises etching the exposure zone, via dry etching such as plasma etching, or reactive ion etching, or both, to form trenches in the semiconductor substrate that comprises the STI test pattern.

Any of the embodiments of the test pattern described above and discussed in the context of FIG. 1 can be used as the STI test pattern in the substrate. The STI test pattern comprises a plurality of test structures, each of the test structures comprising at least two lines comprising a predefined line length, line width, and gap between the lines. At least one of the line length, line width and gap are different between each of the plurality of the test structures.

The method 200 further comprises in step 220, filling the STI test pattern with an insulating material. The insulating material comprises any suitable materials for electrically isolating active areas in a microelectronic device. Non-limiting examples include intrinsic polycrystalline silicon, silicon dioxide, silicon-on-glass, or combinations thereof. In some preferred embodiments the STI test pattern is filled with an insulating material comprising a conformal liner comprising a silicon oxide layer, a silicon nitride layer, or both. The insulating material can be deposited into the trenches comprising the STI test pattern by thermal oxidation, CVD or other suitable techniques.

The method also comprises determining whether or not voids are present in the insulator-filled STI test pattern in step 230. In preferred embodiments of the method 200, the determination of the absence or presence of voids comprises obtaining a microscopic image of a cross-sectional view through the substrate, and then visually inspecting the image. More preferably a single transmission electron microscopic (TEM) or scanning electron microscopic (SEM) image is obtained. Of course, multiple microscopic images are preferred in cases where a single cross-sectional view through the substrate cannot include all of the test structures of the STI test pattern in the substrate.

The design rule for forming an STI structure is accepted or rejected at decision step 240 based on determination of the presence or absence of a void. Of course this decision will depend the minimum size of void that can be detected in the microscopic image. As an example, in some embodiments where a TEM or SEM image of the insulator-filled STI test pattern is obtained, the minimum detectable void has a volume of at least about 1 nm³.

If a particular combination of line length, line width and gap results in the insulator-filled STI test pattern having a void, then the STI design rule being tested for that test structure is rejected in step 250. Alternatively, the STI design rule under test is accepted in step 260 if the STI filling procedure used is capable of filling a void-free test structure built in accordance to the design rule.

One of ordinary skill in the art would appreciate that the STI design rule accepted in step 260 can comprise several different embodiments. In some cases the accepted design rule comprises a minimum acceptable gap, a maximum acceptable line length, a maximal acceptable line width or a combination thereof. In other cases the accepted design rule comprises an allowed range of a ratio of pitch to line length, a ratio of pitch to line width, a ratio of pitch to gap or combinations thereof.

One of ordinary skill in the art would understand how to translate accepted line lengths, line widths or gaps in the STI test pattern to their structural equivalents in an integrated circuit layout. As an example, in some cases a design rule specifying a minimum acceptable gap corresponds to the minimum acceptable gap between to adjacent active areas in a circuit layout. In other cases a design rule specifying a maximal acceptable line width corresponds to the maximal acceptable width of two adjacent active areas in a circuit layout. In yet other cases a maximum accepted line length corresponds to a maximum allowable length for adjacent sides for two different active areas in a circuit layout. One of ordinary skilled in the art would understand how similar structural equivalents could be applied for other allowed ranges or for ratios of pitch to line length, pitch to line width and pitch to gap.

Method steps 210 to 260 can be repeated until all of the STI design rules of interest have been tested. For instance, in some preferred embodiments if it is decided in step 270 that not all of the design rules have been tested then steps 240 to 260 are repeated. In other cases if multiple microscopic images are needed to determine the presence of voids, then step 230 is also repeated. The method 200 can also be applied to test design rules while comparing different types of substrates or insulating materials, or different processes to form and fill the STI structures, or even different methods to determine the presence of voids in STI structures. In such instances steps 210 and 220 are also repeated. Once all of the design rules have been tested, the method is stopped at step 280.

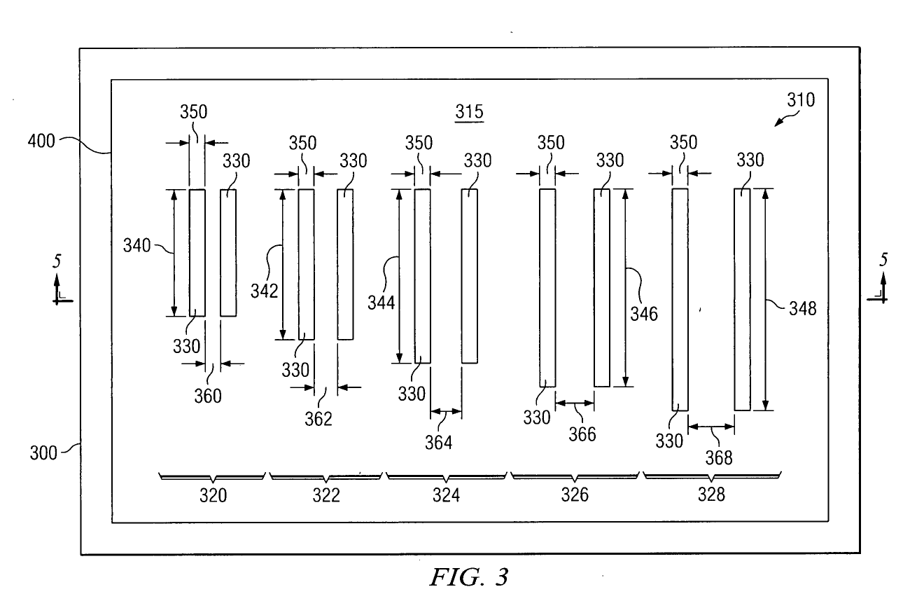

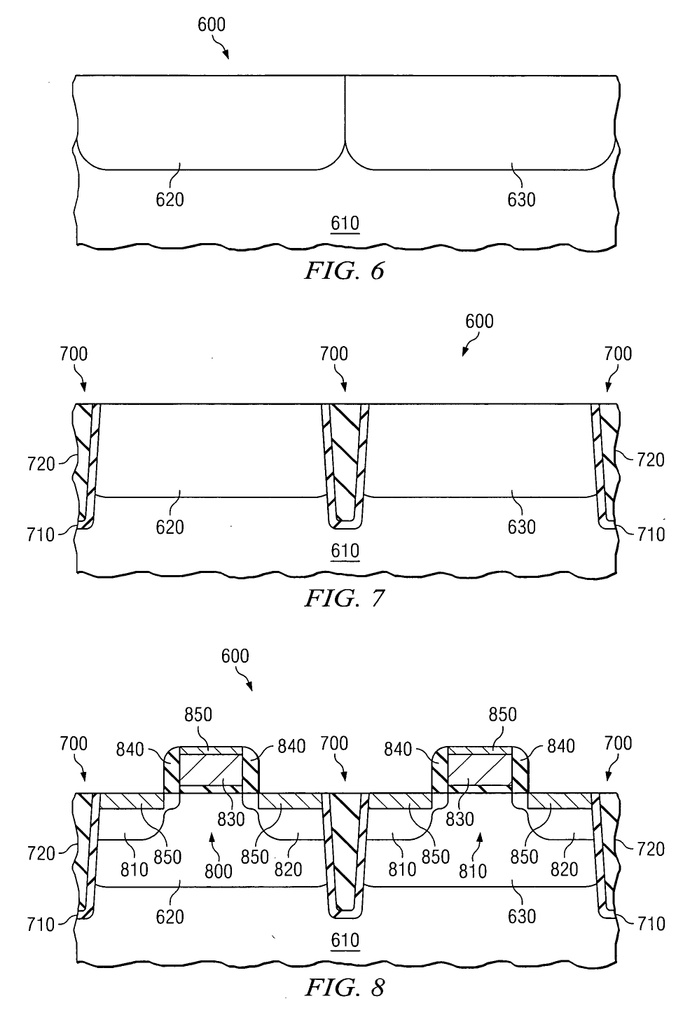

Still another embodiment of the present invention is a method of manufacturing an integrated circuit. FIGS. 3-8 illustrate plan and cross-sectional views at selected stages in the manufacture of an exemplary integrated circuit following the principles of the present invention.

The method of manufacturing the integrated circuit comprises testing design rules for a STI structure, an exemplary method of test being illustrated in FIGS. 3-5. Turning first to FIG. 3, illustrated is a plan view of a test substrate 300 after defining a STI test pattern 310 therein. Any of the above-described methods of defining the test pattern 310 can be used here. For example, lithography and dry etching can be used to define the pattern 310 in a silicon test substrate 300. In some cases, as illustrated in FIG. 3, portions of the test substrate 300 are removed, thereby forming a moat 315 that defines the pattern 310.

Preferably, the test substrate 300 comprises substantially the same material as used for the integrated circuit. For instance, if the integrated circuit is to be formed in a silicon-on-insulator device substrate, then the test substrate 300 preferably comprises a silicon-on-insulator substrate. Preferably, however, the test substrate 300 and the device substrate are not one and the same structure and the STI test pattern 310 is not formed in the device substrate.

Any embodiments of the STI test pattern and methods for forming the pattern discussed above in the context of FIGS. 1 and 2 can be used to form the STI test pattern 310. As noted above, the STI test pattern 310 comprises a plurality of test structures. For example for the STI test pattern 310 depicted in FIG. 3, each of test structures 320, 322, 324, 326, 328 comprising at least two lines 330. The lines 330 each comprise a predefined line length 340, 342, 344, 346, 348 line width 350, and gap 360, 362, 364, 366, 368 between the lines 330. At least one of the line length, line width and gap are different between each of the plurality of test structures. For the embodiment illustrated in FIG. 3, the line width 350 is fixed and the line length 340, 342, 344, 346, 348 and the gap 360, 362, 364, 366, 368 are varied.

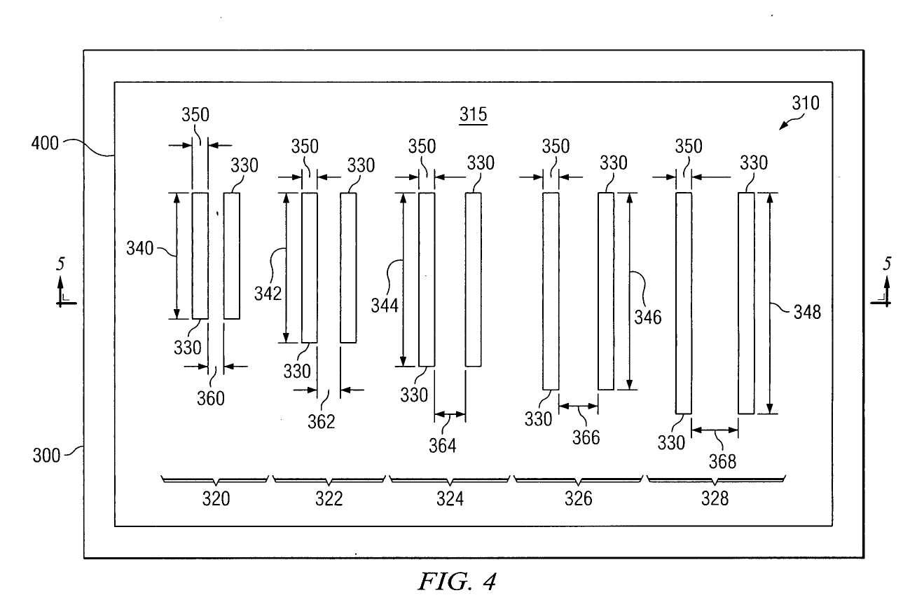

With continuing reference to FIG. 3, FIG. 4 shows a plan view the test substrate 300 after filling the STI test pattern 310 with an insulator 400. In some cases, such as illustrated in FIG. 4 the moat 315 defining the STI test pattern 310 in the substrate 300 is filled with the insulator 400. Again, any of the above-discussed insulators and methods of filling can be used. Preferably the same insulator and STI filling method that will be used in the manufacture of the integrated circuit are also used for filling the STI test pattern 310.

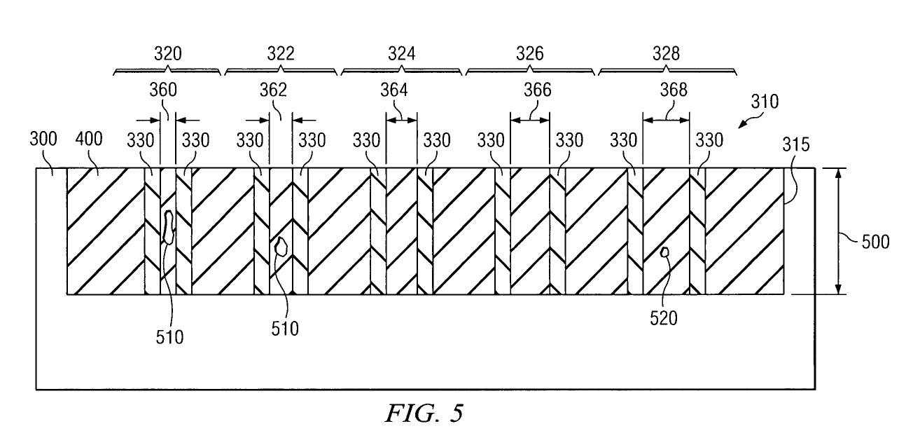

Turning now to FIG. 5, with continuing reference to FIGS. 3-4, presented is a cross-sectional view of the test substrate 300 comprising the insulator-filled STI test pattern 310. The cross-section view shown in FIG. 5 is along view A-A in FIG. 4. As noted above, in the particular embodiment shown in FIGS. 3-5, the test structures 320, 322, 324, 326, 328 comprise lines 330 of a fixed line width 350 and varied line length. Of course, the line length is not depicted in FIG. 5 because this parameter is in the dimension projecting out of and into the plane of the figure. FIG. 5 also illustrates that the gap 360, 362, 364, 366, 368 between lines 330 is also varied from one test structure 320, 322, 324, 326, 328 to the next. As further illustrated, for comparative purposes, it is sometimes preferable for the parameter being tested, such as the gap 360, 362, 364, 366, 368, to be varied by uniform increments between adjacent test structures 320, 322, 324, 326, 328.

The cross-section view presented in FIG. 5 illustrates another parameter that can be varied in the STI test pattern 310: the depth 500 of the lines 330 in the test substrate 300. The depth 500 of the lines 330 in the test substrate 300 advantageously provides information about the capability of the STI fill procedure to form void-free STI structures of various depths. For the particular embodiment shown in FIG. 5, the line depth 500 of the lines 330 of the STI test pattern 310 is fixed. In other cases however, the line depth 500 can be adjusted analogous to that described above for other STI design parameters of line length, line width, gap and pitch.

FIG. 5 also illustrates an exemplary method of determining whether voids are present in the insulator-filled STI test pattern 310. For illustrative purposes, in some cases a cross-sectional microscopic image of the test substrate 300 looks substantially similar to the structure shown in FIG. 5. Visual inspection of the cross-section microscopic image of the test substrate 300 as represented by FIG. 5 is performed to determine whether voids 510 are present in the test structures 320, 322, 324, 326, 328. The test substrate 300 shown in FIG. 5, depicts the presence of voids 510 in test structures 320, 322 having a small gap 360, 362. Voids are not present in test structures 324, 326 having a larger gap 364, 366. Of course the presence or absence of voids in a test structure can also depend on the values of the other design parameters pertaining to the structure. For instance, despite having a large gap 368 a void 520 is present in the test structure 328 having long line lengths 348 (as depicted in FIGS. 3-4).

Based on such determinations, various design rules for a void-free test structure of the insulator-filled STI test pattern can be accepted or rejected. For instance, in the example presented in FIG. 5, design rules that set a minimum acceptable gap that is equal to or less than the values of gap 360, 362 are rejected because the STI fill procedure is not capable of filling such a structure without voids 510 being formed. However, a design rule that sets a minimum acceptable gap equal to the values of gap 364 or larger is accepted. Additionally, the design rule setting an acceptable gap can be modified to a range corresponding to the values for gap 364 to gap 366, if the effect of line length, or other parameters, on void formation 520 is considered. Analogous test structures and procedures are used to test design rules for line length and line width, resulting in design rules specifying a maximum acceptable line length and a maximal acceptable line width or ranges thereof. Similar procedures can be used to test and accept design rules for pitch, pitch ratios, depth and the like.

With continuing reference to FIGS. 3-5, FIG. 6 presents a cross-sectional view of an integrated circuit 600 at an intermediate stage of manufacture. The method of manufacturing the integrated circuit 600 comprises forming active areas 610, 620 in a device substrate 630. Any conventional process can be used to form the active areas 610, 620. In some preferred embodiments, certain areas of the device substrate 630 are masked, and n-type or p-type dopants are implanted into unmasked areas of the substrate 630 to form active areas 610 comprising an n-doped well and active area 620 comprising a p-doped well. One of ordinary skill in the art would be familiar with the type and concentration of dopants, as well as implantation and annealing procedures, that are suitable to form the active areas 610, 620.

Turning now to FIG. 7, while maintaining reference to FIGS. 3-6, depicted is the partially completed integrated circuit 600 after forming STI structures 700 in the device substrate 620 to electrically isolate the active areas 610. The STI structures 700 obey the design rules that are tested and accepted as discussed above and described in the context of FIGS. 1-5. Preferably the STI structures 700 are formed after testing the design rules for STI structures.

Any of the material and processes described above can be used to form the STI structure 700. For example, a mask for a STI structures 700 is patterned using suitable patterning processes, such a photolithography for form a mask, followed by a dry etching process in unmasked areas to form an opening 710 for the STI structures 700. The shallow trench 710 is then filled with an insulator. For the particular embodiment illustrated the insulator comprises one or more liner layer 710 comprising silicon dioxide, silicon nitride or both formed via a thermal growth or low-pressure CVD process. Filling with the insulator can also comprise the use of similar procedures to form a plug 720 comprising a semiconductor or dielectric material such as polycrystalline silicon or silicon dioxide.

Referring now to FIG. 8, with continuing reference to FIGS. 3-7, shown is the integrated circuit 600 after forming microelectronic devices 800, 810 on the active areas 610. In some embodiments the microelectronic devices 800, 810 comprises an MOS transistor. One of ordinary skill in the art would be familiar with the techniques to form device components such as source/drain structures 820, 830, gate 830, gate side walls 840, electrodes 850 over the source/drain structures 820, 830 and gate 830. Embodiments of the microelectronic devices 800, 810 comprise nMOS or pMOS transistors, CMOS, BiCMOS devices, bipolar or other types of active or passive integrated circuit components, and combinations thereof. In some preferred embodiments the microelectronic devices 800, 810 comprise a static random access memory (SRAM) device, such as 5-transistor or 6-transistor SRAM devices.

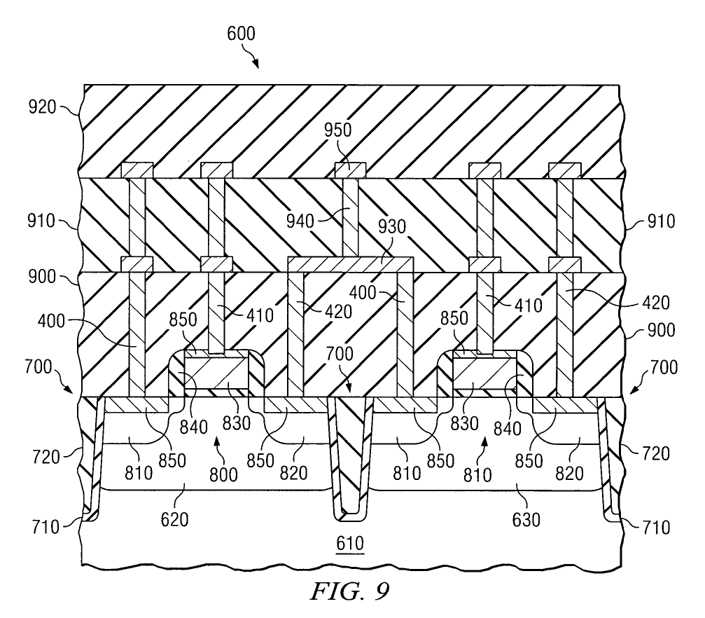

Turning now to FIG. 9, with continued reference to FIGS. 3-8, illustrated is the integrated circuit 600 after forming one or more insulating layer 900, 910, 920 over the microelectronic devices 800, 810. In some embodiments, forming the insulating layer 900, 910, 920 comprises forming a silicon oxide dielectric layer over the microelectronic devices 800, 810. FIG. 9 further illustrates the partially completed integrated circuit 600 after forming interconnects 930, 940, 950 in or on the insulating layers 900, 910, 920, and interconnecting the microelectronic devices to form an operative integrated circuit 600.

Although the present invention has been described in detail, those skilled in the art should understand that they could make various changes, substitutions and alterations herein without departing from the scope of the invention in its broadest form.

What is claimed is:

1. A shallow trench isolation (STI) test pattern, comprising:
a plurality of test structures, each of said test structures comprising at least two lines comprising a predefined line length, line width, and gap between said lines, and
wherein at least one of said line length, said line width and said gap are different between each of said plurality of said test structures.

2. The STI test pattern as recited in claim 1, wherein said lines in any one of said test structures comprise a substantially equal line length and line width.

3. The STI test pattern as recited in claim 1, wherein each of said test structures comprise at least three of said lines.

4. The STI test pattern as recited in claim 3, wherein said gaps between pairs of adjacent said lines within any one of said test structures are substantially equal to each other.

5. The STI test pattern as recited in claim 1, wherein one of said line length, said line width and said gap is different between adjacent test structures.

6. The STI test pattern as recited in claim 1, wherein two of said line length, said line width and said gap are different between adjacent test structures.

7. The STI test pattern as recited in claim 1, wherein said line length, said line width and said gap are different between adjacent test structures.

8. The STI test pattern as recited in claim 1, wherein said line length ranges from about 180 to about 1000 nanometers, said line width ranges from about 90 to about 120 nanometers, and said gap ranges from about 60 to about 90 nanometers.

9. The STI test pattern as recited in claim 1, wherein at least one said line width and said gap define a pitch and said pitch is varied between said test structures.

10. The STI test pattern as recited in claim 9, wherein a ratio of said pitch to said line length ranges from about 0.1:1 to about 1:1, a ratio of said pitch to said line width ranges from about 1.5:1 to about 2:1 and a ratio of said pitch to said gap ranges from about 0.2:1 to about 0.7:1.

11. The STI test pattern as recited in claim 1, wherein each one of said plurality of test structures are configured to define a device under test (DUT) module in a reticle and each one of said lines define a chrome in said DUT test module.

12. The STI test pattern as recited in claim 1, wherein said plurality of test structures are configured to define exposure zones over a substrate.

13. A method of testing a shallow trench isolation (STI) design rule comprising:
defining a STI test pattern in a substrate, wherein said STI test pattern comprises:
a plurality of test structures, each of said test structures comprising at least two lines comprising a predefined line length, line width, and gap between said lines, and
wherein at least one of said line length, said line width and said gap are different between each of said plurality of said test structures;
filling said STI test pattern with an insulating material;
determining whether voids are present in said insulator-filled STI test pattern;
accepting a design rule for a void-free test structure of said insulator-filled STI test pattern.

14. The method recited in claim 13, wherein said accepted design rule comprises a minimum acceptable gap, a maximum acceptable line length, a maximal acceptable line width or a combination thereof.

15. The method as recited in claim 13, wherein said accepted design rule comprises an allowed range of a ratio of pitch to line length, a ratio of pitch to line width, a ratio of pitch to gap or combinations thereof, wherein said pitch is defined as said line width plus said gap.

16. The method of fabrication recited in claim 13, wherein said determining comprises obtaining a single microscopic image of a cross-section view through said substrate.

17. A method of manufacturing an integrated circuit, comprising:
testing design rules for a shallow trench isolation (STI) structure comprising:
defining a STI test pattern in a test substrate, wherein said STI test pattern comprises:
a plurality of test structures, each of said test structures comprising at least two lines, said lines comprising a predefined line length, line width, and gap between said lines, and
wherein at least one of said line length, said line width and said gap are different between each of said plurality of said test structures;
filling said STI test pattern with an insulator;
determining whether voids are present in said insulator-filled STI test pattern; and
accepting a design rule for a void-free test structure of said insulator-filled STI test pattern;
forming active areas in a device substrate; and
forming STI structures in said device substrate to electrically isolate said active areas, wherein said STI structures obey said accepted design rule.

18. The method as recited in claim 17, wherein said accepted design rule comprises a minimum acceptable gap a maximum acceptable line length, a maximal acceptable line width or combination thereof.

19. The method as recited in claim 17, further comprising forming microelectronic devices on said active areas and interconnecting said microelectronic devices to form an operative circuit.

20. The method as recited in claim 19, wherein said microelectronic devices comprise an SRAM device.
